(19) United States
(12) Patent Application Publication
(10) Pub. No.: US 2023/0356146 A1
(43) Pub. Date: Nov. 9, 2023

(54) DESICCANT ASSEMBLY FOR HUMIDITY CONTROL WITHIN A SENSOR HOUSING

(71) Applicant: LG INNOTEK CO., LTD., Seoul (KR)

(72) Inventors: Bayard G. GARDINEER, Pittsburgh, PA (US); Christopher John TROWBRIDGE, Pittsburgh, PA (US); Ying XIANG, Pittsburgh, PA (US)

(73) Assignee: LG INNOTEK CO., LTD., Seoul (KR)

(21) Appl. No.: 18/153,209

(22) Filed: Jan. 11, 2023

Related U.S. Application Data
(60) Provisional application No. 63/399,099, filed on Aug. 18, 2022.

(51) Int. Cl. B01D 53/26; H05K 5/02

(52) U.S. Cl. CPC B01D 53/261; H05K 5/0215; B01D 2325/36; B01D 2257/80

(57) ABSTRACT

In some implementations, a desiccant assembly within a sensor housing may include a desiccant chamber configured to hold a desiccant element; a transfer window positioned between the desiccant chamber and a sensor chamber of the sensor housing; and a permeable membrane covering the transfer window and configured to allow water vapor to transfer from the sensor chamber to the desiccant chamber.

### CROSS-REFERENCE TO RELATED APPLICATION

This patent application claims priority to U.S. Provisional Patent Application No. 63/399,099, filed on Aug. 18, 2022, entitled “Desiccant Integration for Enclosure Humidity Control” and assigned to the assignee hereof. The disclosure of the prior application is considered part of and is incorporated by reference into this patent application.

### BACKGROUND

An autonomous vehicle (or AV) is a vehicle having a processor, programming instructions, and drivetrain components that are controllable by the processor without requiring a human operator. An autonomous vehicle may be fully autonomous in that the autonomous vehicle does not require a human operator for most or all driving conditions and functions, or an autonomous vehicle may be semi-autonomous in that a human operator may be required in certain conditions or for certain operations, or that a human operator may override the autonomous vehicle's autonomous system and may take control of the autonomous vehicle.

### SUMMARY

In some implementations, a desiccant assembly within a sensor housing includes a desiccant chamber configured to hold a desiccant element; a transfer window positioned between the desiccant chamber and a sensor chamber of the sensor housing; and a permeable membrane covering the transfer window and configured to allow water vapor to transfer from the sensor chamber to the desiccant chamber.

In some implementations, a lidar system includes a sensor housing including a sensor chamber; a sensor disposed within the sensor chamber; and a desiccant assembly disposed within the sensor housing, the desiccant assembly comprising a desiccant chamber configured to hold a desiccant element; and a permeable membrane positioned between the desiccant chamber and the sensor chamber and configured to allow water vapor to transfer from the sensor chamber to the desiccant chamber.

In some implementations, an equipment housing includes an equipment chamber configured to hold electronic equipment; and a desiccant assembly, comprising a desiccant chamber configured to hold a desiccant element; and a transfer assembly positioned between the desiccant chamber and the equipment chamber, wherein the transfer assembly is configured to allow water vapor to transfer from the equipment chamber to the desiccant chamber and to prevent particulate matter from transferring from the desiccant chamber to the equipment chamber.

In some implementations, a method of manufacturing a sensor housing includes providing a desiccant chamber configured to hold a desiccant element; positioning a transfer window between the desiccant chamber and a sensor chamber of the sensor housing; and disposing a permeable membrane over the transfer window, wherein the permeable membrane is configured to allow water vapor to transfer from the sensor chamber to the desiccant chamber.

### BRIEF DESCRIPTION OF THE DRAWINGS

FIG. 1 is a diagram of an example environment in which an autonomous vehicle may operate, in accordance with some aspects of the disclosure.

FIG. 2 is a diagram of an example on-board system of an autonomous vehicle, in accordance with some aspects of the disclosure.

FIG. 3 is a diagram of an example lidar system, in accordance with some aspects of the disclosure.

FIG. 4A is a perspective diagram of an example sensor housing, in accordance with some aspects of the disclosure.

FIG. 4B is an exploded perspective diagram of the example sensor housing, with the housing shell removed, in accordance with some aspects of the disclosure.

FIG. 4C is another exploded perspective diagram of the example sensor housing, with the housing shell removed, in accordance with some aspects of the disclosure.

FIG. 4D is another exploded perspective diagram of the example sensor housing, with the housing shell removed, in accordance with some aspects of the disclosure.

FIG. 4E is a perspective diagram of an example desiccant assembly body, in accordance with some aspects of the disclosure.

FIG. 4F is another perspective diagram of the example desiccant assembly body, in accordance with some aspects of the disclosure.

FIG. 4G is a top plan diagram of the example desiccant assembly body, in accordance with some aspects of the disclosure.

FIG. 5 is a flowchart of an example method associated with manufacturing a sensor housing, in accordance with some aspects of the disclosure.

### DETAILED DESCRIPTION

The following detailed description of example implementations refers to the accompanying drawings, which are incorporated herein and form a part of the specification. The same reference numbers in different drawings may identify the same or similar elements. In general, the left-most digit(s) of a reference number identifies the drawing in which the reference number first appears.

Autonomous vehicles (“AVs”) may use a number of different sensors for situational awareness. The sensors, which may be part of a self-driving system (“SDS”) in the AV, may include one or more of a camera, a lidar (Light Detection and Ranging) device, and/or an inertial measurement unit (“IMU”), among other examples. Sensors such as cameras and lidar may be used to capture and analyze scenes around the AV to detect objects. Sometimes, a scene representation, such as point cloud obtained from the AV's lidar, may be combined with one or more images from one or more cameras to obtain further insights to the scene or situation around the AV. It can be appreciated that sensors external to the vehicle, such as cameras and lidar sensors, may be subjected to extreme weather conditions and subsequent fluctuations such as, for example, high temperatures, low temperatures, temperature changes, snow conditions, extreme wind conditions, and/or rain, among other examples. Weather conditions and fluctuations in weather conditions may cause humidity (e.g., water vapor) to build up within and/or to ingress into a sensor enclosure, causing the sensor to perform at suboptimal levels. For example, condensation can occur when temperatures change at a sufficiently high rate.

Some implementations described herein limit condensation buildup within a sensor assembly, thereby mitigating negative effects upon electronics within the sensor assembly due to condensation. For example, some aspects may facilitate reduction of the effects of condensation upon optical sensors operating in outdoor environments, such as those integrated on the external portion of vehicles (e.g., AVs). According to some aspects, a sensor assembly may include a desiccant assembly within a sensor housing. The desiccant assembly may include a desiccant chamber configured to hold at least one desiccant element (e.g., one or more desiccant blocks) and may include a transfer window positioned between the desiccant chamber and a sensor chamber of the sensor housing. A permeable membrane may cover the transfer window and may be configured to allow water vapor to transfer from the sensor chamber to the desiccant chamber, while preventing liquid water and particulate matter from transferring from the desiccant chamber to the sensor chamber. The permeable membrane and/or a set of dimensions of the at least one transfer window may be configured so that a leak rate corresponding to a transfer of water vapor from the sensor chamber to the desiccant chamber causes prevention of condensation of water within the sensor chamber.

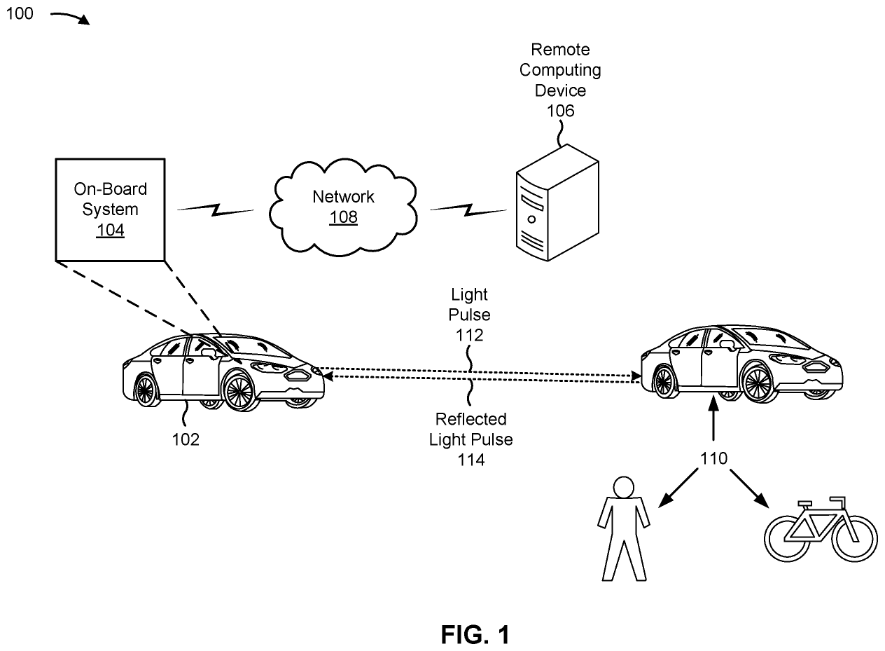

FIG. 1 is a diagram of an example environment 100 in which an autonomous vehicle may operate, in accordance with some aspects of the disclosure. The environment 100 may include, for example, a vehicle 102, an on-board system 104 of the vehicle 102, a remote computing device 106, and/or a network 108. As further shown, the environment 100 may include one or more objects 110 that the vehicle 102 is configured to detect.

The vehicle 102 may include any moving form of conveyance that is capable of carrying one or more human occupants and/or cargo and that is powered by any form of energy. The vehicle 102 may include, for example, a land vehicle (e.g., a car, a truck, a van, or a train), an aircraft (e.g., an unmanned aerial vehicle or a drone), or a watercraft. In the example of FIG. 1, the vehicle 102 is a land vehicle, and is shown as a car. Furthermore, the vehicle 102 is an autonomous vehicle in the example of FIG. 1. An autonomous vehicle (or AV) is a vehicle having a processor, programming instructions, and drivetrain components that are controllable by the processor without requiring a human operator. An autonomous vehicle may be fully autonomous in that the autonomous vehicle does not require a human operator for most or all driving conditions and functions, or an autonomous vehicle may be semi-autonomous in that a human operator may be required in certain conditions or for certain operations, or that a human operator may override the autonomous vehicle's autonomous system and may take control of the autonomous vehicle.

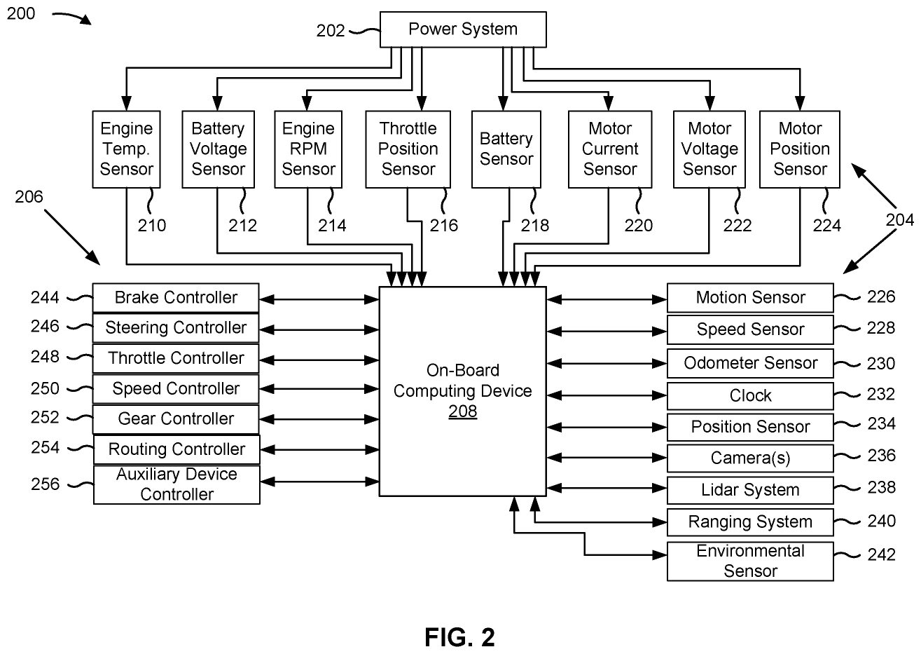

As shown in FIG. 1, the vehicle 102 may include an on-board system 104 that is integrated into and/or coupled with the vehicle 102. In general, the on-board system 104 may be used to control the vehicle 102, to sense information about the vehicle 102 and/or an environment in which the vehicle 102 operates, to detect one or more objects 110 in a proximity of the vehicle, to provide output to or receive input from an occupant of the vehicle 102, and/or to communicate with one or more devices remote from the vehicle 102, such as another vehicle and/or the remote computing device 106. The on-board system 104 is described in more detail below in connection with FIG. 2.

In some implementations, the vehicle 102 may travel along a road in a semi-autonomous or autonomous manner. The vehicle 102 may be configured to detect objects 110 in a proximity of the vehicle 102. An object 110 may include, for example, another vehicle (e.g., an autonomous vehicle or a non-autonomous vehicle that requires a human operator for most or all driving conditions and functions), a cyclist (e.g., a rider of a bicycle, electric scooter, or motorcycle), a pedestrian, a road feature (e.g., a roadway boundary, a lane marker, a sidewalk, a median, a guard rail, a barricade, a sign, a traffic signal, a railroad crossing, or a bike path), and/or another object that may be on a roadway or in proximity of a roadway, such as a tree or an animal.

To detect objects 110, the vehicle 102 may be equipped with one or more sensors, such as a lidar system, as described in more detail elsewhere herein. The lidar system may be configured to transmit a light pulse 112 to detect objects 110 located within a distance or range of distances of the vehicle 102. The light pulse 112 may be incident on an object 110 and may be reflected back to the lidar system as a reflected light pulse 114. The reflected light pulse 114 may be incident on the lidar system and may be processed to determine a distance between the object 110 and the vehicle 102. The reflected light pulse 114 may be detected using, for example, a photodetector or an array of photodetectors positioned and configured to receive the reflected light pulse 114. In some implementations, a lidar system may be included in another system other than a vehicle 102, such as a robot, a satellite, and/or a traffic light, or may be used as a standalone system. Furthermore, implementations described herein are not limited to autonomous vehicle applications and may be used in other applications, such as robotic applications, radar system applications, metric applications, and/or system performance applications.

The lidar system may provide lidar data, such as information about a detected object 110 (e.g., information about a distance to the object 110, a speed of the object 110, and/or a direction of movement of the object 110), to one or more other components of the on-board system 104. Additionally, or alternatively, the vehicle 102 may transmit lidar data to the remote computing device 106 (e.g., a server, a cloud computing system, and/or a database) via the network 108. The remote computing device 106 may be configured to process the lidar data and/or to transmit a result of processing the lidar data to the vehicle 102 via the network 108.

The network 108 may include one or more wired and/or wireless networks. For example, the network 108 may include a wireless wide area network (e.g., a cellular network or a public land mobile network), a local area network (e.g., a wired local area network or a wireless local area network (WLAN), such as a Wi-Fi network), a personal area network (e.g., a Bluetooth network), a near-field communication network, a telephone network, a private network, the Internet, and/or a combination of these or other types of networks. The network 108 enables communication among the devices of environment 100.

As indicated above, FIG. 1 is provided as an example. Other examples may differ from what is described with regard to FIG. 1. The number and arrangement of devices shown in FIG. 1 are provided as an example. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) shown in FIG. 1 may perform one or more functions described as being performed by another set of devices shown in FIG. 1.

FIG. 2 is a diagram of an example on-board system 200 of an autonomous vehicle, in accordance with some aspects of the disclosure. In some implementations, the on-board system 200 may correspond to the on-board system 104 included in the vehicle 102, as described above in connection with FIG. 1. As shown in FIG. 2, the on-board system 200 may include one or more of the illustrated components 202-256. The components of the on-board system 200 may include, for example, a power system 202, one or more sensors 204, one or more controllers 206, and/or an on-board computing device 208. The components of the on-board system 200 may communicate via a bus (e.g., one or more wired and/or wireless connections), such as a controller area network (CAN) bus.

The power system 202 may be configured to generate mechanical energy for the vehicle 102 to move the vehicle 102. For example, the power system 202 may include an engine that converts fuel to mechanical energy (e.g., via combustion) and/or a motor that converts electrical energy to mechanical energy.

The one or more sensors 204 may be configured to detect operational parameters of the vehicle 102 and/or environmental conditions of an environment in which the vehicle 102 operates. For example, the one or more sensors 204 may include an engine temperature sensor 210, a battery voltage sensor 212, an engine rotations per minute (RPM) sensor 214, a throttle position sensor 216, a battery sensor 218 (to measure current, voltage, and/or temperature of a battery), a motor current sensor 220, a motor voltage sensor 222, a motor position sensor 224 (e.g., a resolver and/or encoder), a motion sensor 226 (e.g., an accelerometer, gyroscope and/or inertial measurement unit), a speed sensor 228, an odometer sensor 230, a clock 232, a position sensor 234 (e.g., a global navigation satellite system (GNSS) sensor and/or a global positioning system (GPS) sensor), one or more cameras 236, a lidar system 238, one or more other ranging systems 240 (e.g., a radar system and/or a sonar system), and/or an environmental sensor 242 (e.g., a precipitation sensor and/or ambient temperature sensor).

The one or more controllers 206 may be configured to control operation of the vehicle 102. For example, the one or more controllers 206 may include a brake controller 244 to control braking of the vehicle 102, a steering controller 246 to control steering and/or direction of the vehicle 102, a throttle controller 248 and/or a speed controller 250 to control speed and/or acceleration of the vehicle 102, a gear controller 252 to control gear shifting of the vehicle 102, a routing controller 254 to control navigation and/or routing of the vehicle 102 (e.g., using map data), and/or an auxiliary device controller 256 to control one or more auxiliary devices associated with the vehicle 102, such as a testing device, an auxiliary sensor, and/or a mobile device transported by the vehicle 102.

The on-board computing device 208 may be configured to receive sensor data from one or more sensors 204 and/or to provide commands to one or more controllers 206. For example, the on-board computing device 208 may control operation of the vehicle 102 by providing a command to a controller 206 based on sensor data received from a sensor 204. In some implementations, the on-board computing device 208 may be configured to process sensor data to generate a command. The on-board computing device 208 may include memory, one or more processors, an input component, an output component, and/or a communication component, as described in more detail elsewhere herein.

As an example, the on-board computing device 208 may receive navigation data, such as information associated with a navigation route from a start location of the vehicle 102 to a destination location for the vehicle 102. In some implementations, the navigation data is accessed and/or generated by the routing controller 254. For example, the routing controller 254 may access map data and identify possible routes and/or road segments that the vehicle 102 can travel to move from the start location to the destination location. In some implementations, the routing controller 254 may identify a preferred route, such as by scoring multiple possible routes, applying one or more routing techniques (e.g., minimum Euclidean distance, Dijkstra's algorithm, and/or Bellman-Ford algorithm), accounting for traffic data, and/or receiving a user selection of a route, among other examples. The on-board computing device 208 may use the navigation data to control operation of the vehicle 102.

As the vehicle travels along the route, the on-board computing device 208 may receive sensor data from various sensors 204. For example, the position sensor 234 may provide geographic location information to the on-board computing device 208, which may then access a map associated with the geographic location information to determine known fixed features associated with the geographic location, such as streets, buildings, stop signs, and/or traffic signals, which may be used to control operation of the vehicle 102.

In some implementations, the on-board computing device 208 may receive one or more images captured by one or more cameras 236, may analyze the one or more images (e.g., to detect object data), and may control operation of the vehicle 102 based on analyzing the images (e.g., to avoid detected objects). Additionally, or alternatively, the on-board computing device 208 may receive object data associated with one or more objects detected in a vicinity of the vehicle 102 and/or may generate object data based on sensor data. The object data may indicate the presence or absence of an object, a location of the object, a distance between the object and the vehicle 102, a speed of the object, a direction of movement of the object, an acceleration of the object, a trajectory (e.g., a heading) of the object, a shape of the object, a size of the object, a footprint of the object, and/or a type of the object (e.g., a vehicle, a pedestrian, a cyclist, a stationary object, or a moving object). The object data may be detected by, for example, one or more cameras 236 (e.g., as image data), the lidar system 238 (e.g., as lidar data) and/or one or more other ranging systems 240 (e.g., as radar data or sonar data). The on-board computing device 208 may process the object data to detect objects in a proximity of the vehicle 102 and/or to control operation of the vehicle 102 based on the object data (e.g., to avoid detected objects).

In some implementations, the on-board computing device 208 may use the object data (e.g., current object data) to predict future object data for one or more objects. For example, the on-board computing device 208 may predict a future location of an object, a future distance between the object and the vehicle 102, a future speed of the object, a future direction of movement of the object, a future acceleration of the object, and/or a future trajectory (e.g., a future heading) of the object. For example, if an object is a vehicle and map data indicates that the vehicle is at an intersection, then the on-board computing device 208 may predict whether the object will likely move straight or turn. As another example, if the sensor data and/or the map data indicates that the intersection does not have a traffic light, then the on-board computing device 208 may predict whether the object will stop prior to entering the intersection.

The on-board computing device 208 may generate a motion plan for the vehicle 102 based on sensor data, navigation data, and/or object data (e.g., current object data and/or future object data). For example, based on current locations of objects and/or predicted future locations of objects, the on-board computing device 208 may generate a motion plan to move the vehicle 102 along a surface and avoid collision with other objects. In some implementations, the motion plan may include, for one or more points in time, a speed of the vehicle 102, a direction of the vehicle 102, and/or an acceleration of the vehicle 102. Additionally, or alternatively, the motion plan may indicate one or more actions with respect to a detected object, such as whether to overtake the object, yield to the object, pass the object, or the like. The on-board computing device 208 may generate one or more commands or instructions based on the motion plan, and may provide those command(s) to one or more controllers 206 for execution.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single components, or a single components shown in FIG. 2 may be implemented as multiple, distributed components. Additionally, or alternatively, a set of components (e.g., one or more components) shown in FIG. 2 may perform one or more functions described as being performed by another set of components shown in FIG. 2. For example, although some components of FIG. 2 are primarily associated with land vehicles, other types of vehicles are within the scope of the disclosure. As an example, an on-board system of an aircraft may not include the brake controller 244 and/or the gear controller 252, but may include an altitude sensor. As another example, an on-board system of a watercraft may include a depth sensor.

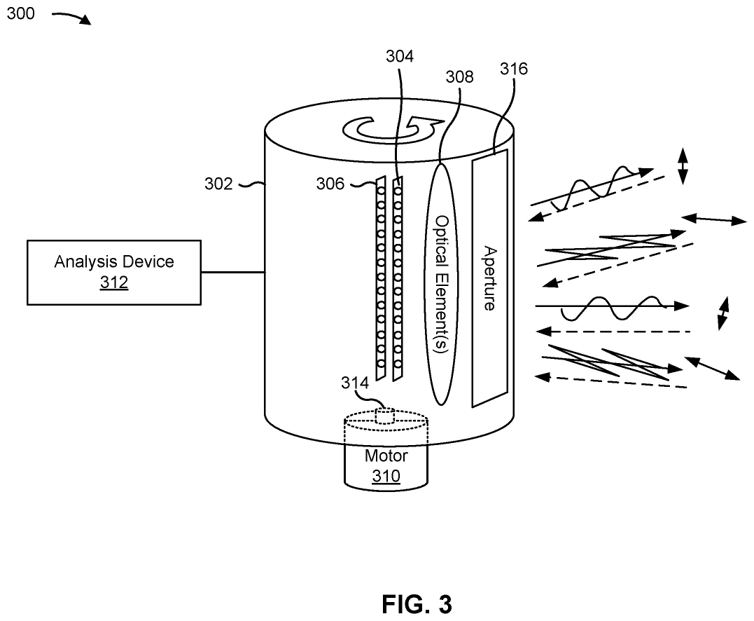

FIG. 3 is a diagram of an example lidar system 300, in accordance with some aspects of the disclosure. In some implementations, the lidar system 300 may correspond to the lidar system 238 of FIG. 2. As shown in FIG. 3, the lidar system may include a housing 302, a light emitter system 304, a light detector system 306, an optical element structure 308, a motor 310, and an analysis device 312.

The housing 302 may be rotatable (e.g., by 360 degrees) around an axle 314 (or hub) of the motor 310. The housing 302 may include an aperture 316 (e.g., an emitter and/or receiver aperture) made of a material transparent to light. Although a single aperture 316 is shown in FIG. 3, the housing 302 may include multiple apertures 316 in some implementations. The lidar system 300 may emit light through one or more apertures 316 and may receive reflected light back through one or more apertures 316 as the housing 302 rotates around components housed within the housing 302. Alternatively, the housing 302 may be a stationary structure (e.g., that does not rotate), at least partially made of a material that is transparent to light, with rotatable components inside of the housing 302.

The housing 302 may house the light emitter system 304, the light detector system 306, and/or the optical element structure 308. The light emitter system 304 may be configured and/or positioned to generate and emit pulses of light through the aperture 316 and/or through a transparent material of the housing 302. For example, the light emitter system 304 may include one or more light emitters, such as laser emitter chips or other light emitting devices. The light emitter system 304 may include any number of individual light emitters (e.g., 8 emitters, 64 emitters, or 128 emitters), which may emit light at substantially the same intensity or of varying intensities. The light detector system 306 may include a photodetector or an array of photodetectors configured and/or positioned to receive light reflected back through the housing 302 and/or the aperture 316.

The optical element structure 308 may be positioned between the light emitter system 304 and the housing 302, and/or may be positioned between the light detector system 306 and the housing 302. The optical element structure 308 may include one or more lenses, waveplates, and/or mirrors that focus and direct light that passes through the optical element structure 308. The light emitter system 304, the light detector system 306, and/or the optical element structure 308 may rotate with a rotatable housing 302 or may rotate inside of a stationary housing 302.

The analysis device 312 may be configured to receive (e.g., via one or more wired and/or wireless connections) sensor data collected by the light detector system 306, analyze the sensor data to measure characteristics of the received light, and generate output data based on the sensor data. In some implementations, the analysis device 312 may provide the output data to another system that can control operations and/or provide recommendations with respect to an environment from which the sensor data was collected. For example, the analysis device 312 may provide the output data to the on-board system 104 (e.g., the on-board computing device 208) of the vehicle 102 to enable the on-board system 104 to process the output data and/or use the output data (or the processed output data) to control operation of the vehicle 102. The analysis device 312 may be integrated into the lidar system 300 or may be external from the lidar system 300 and communicatively connected to the lidar system 300 via a network. The analysis device 312 may include memory, one or more processors, an input component, an output component, and/or a communication component, as described in more detail elsewhere herein.

As indicated above, FIG. 3 is provided as an example. Other examples may differ from what is described with regard to FIG. 3. The number and arrangement of components shown in FIG. 3 are provided as an example. In practice, there may be additional components, fewer components, different components, or differently arranged components than those shown in FIG. 3. Furthermore, two or more components shown in FIG. 3 may be implemented within a single components, or a single components shown in FIG. 3 may be implemented as multiple, distributed components. Additionally, or alternatively, a set of components (e.g., one or more components) shown in FIG. 3 may perform one or more functions described as being performed by another set of components shown in FIG. 3.

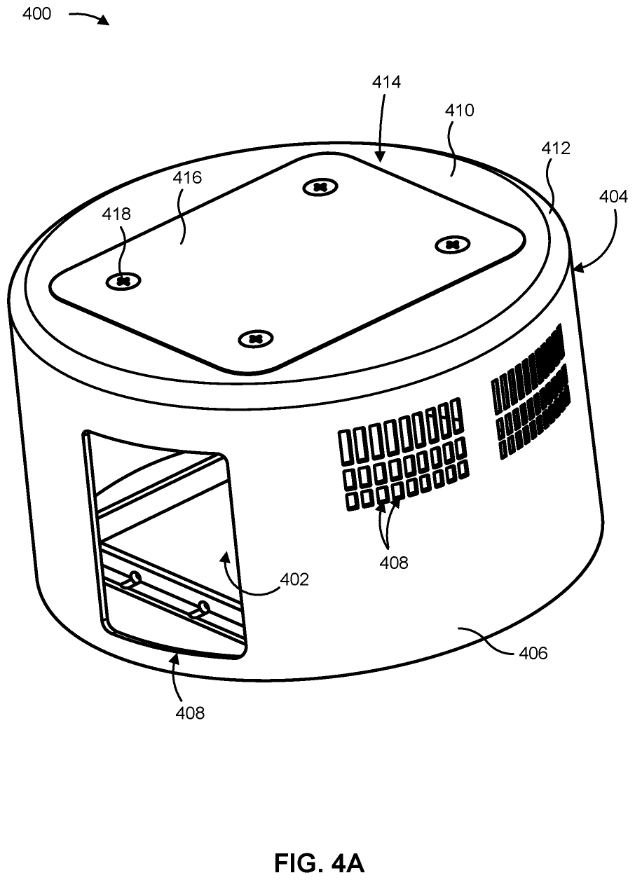

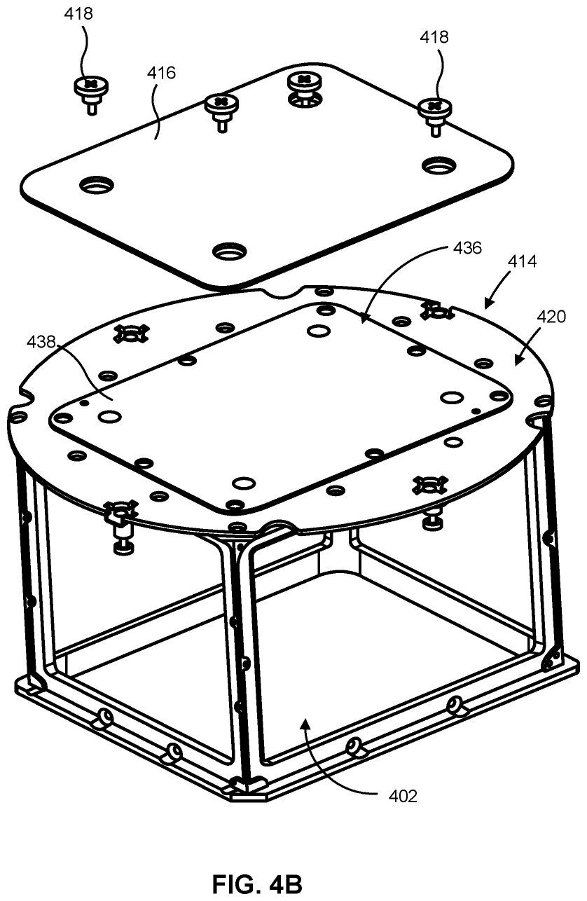

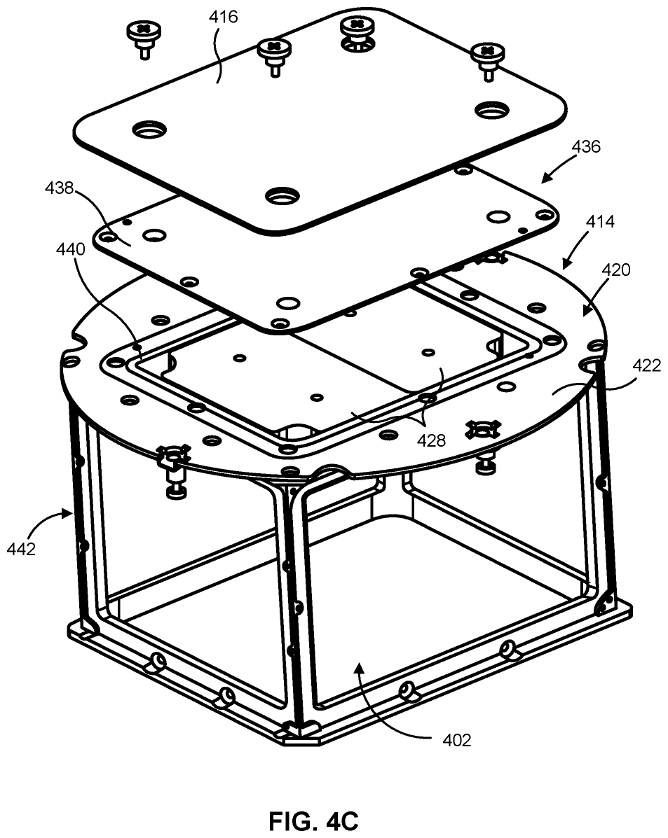

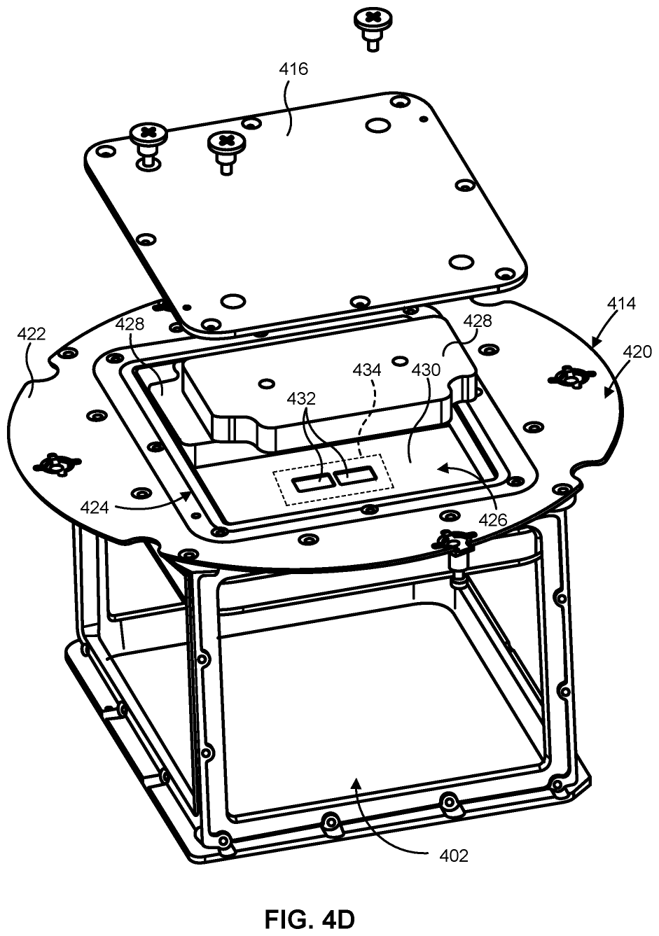

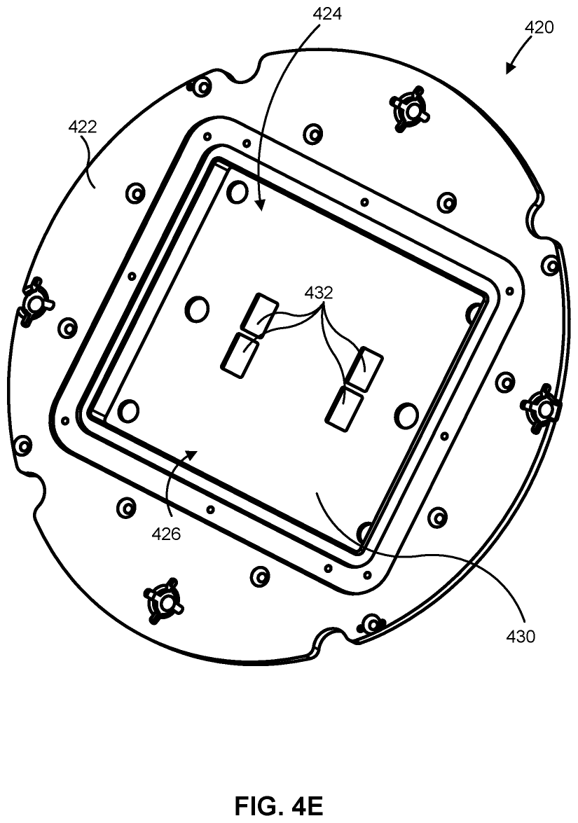

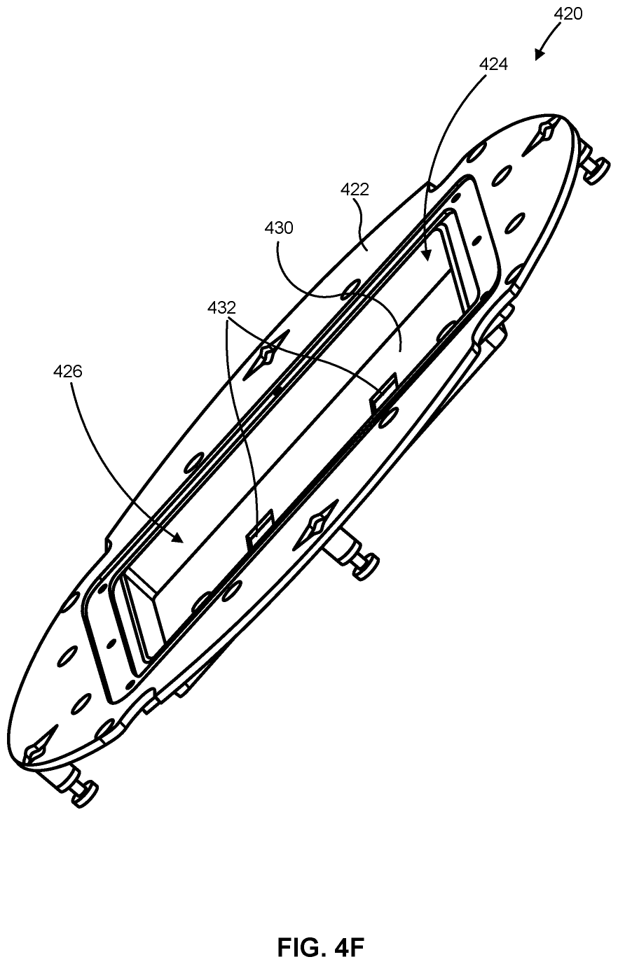

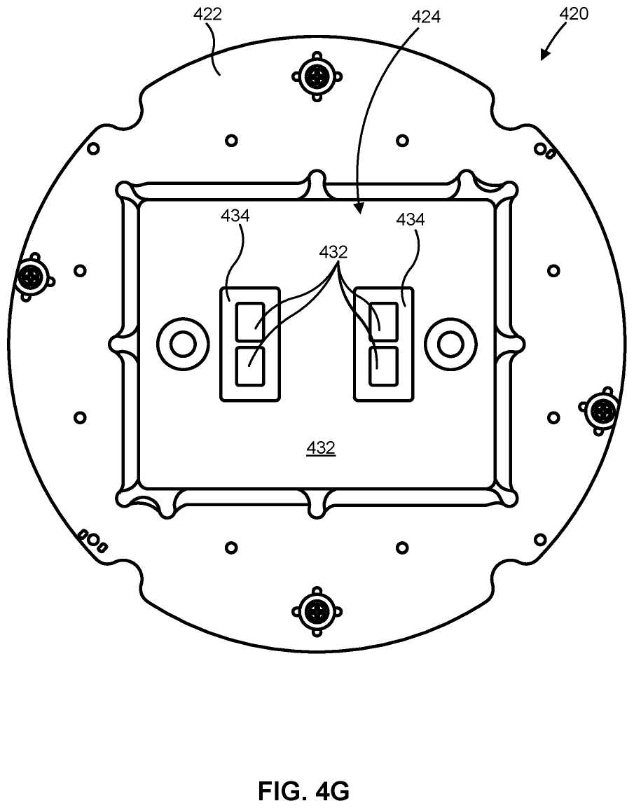

FIGS. 4A-4G are diagrams of an example sensor housing 400, in accordance with some aspects of the disclosure. In some aspects, the sensor housing 400 may be, be similar to, include, or be included in, the housing 302 of the lidar system 300 depicted in FIG. 3. In some other aspects, the sensor housing 400 may be a housing associated with any other type of sensor such as, for example, an imaging device (e.g., a camera and/or a video camera), a radar device, and/or a motion sensor, among other examples.

FIG. 4A is a perspective diagram of the example sensor housing 400, in accordance with some aspects of the disclosure. As shown in FIG. 4A, for example, the sensor housing 400 may include a sensor chamber 402 enclosed by a housing shell 404. The housing shell 404 may include a perimeter wall 406 having a number of apertures 408. The housing shell 404 may include an upper wall 410 that is coupled with the perimeter wall 406 via a beveled edge 412. In some aspects, the interface between the upper wall 410 and the perimeter wall 406 may be at least approximately perpendicular, for example, without including the beveled edge 412. A top plate 416 may be removably attachable to the upper wall 410 using fasteners 418 (e.g., screws).

FIGS. 4B-4D are exploded perspective diagrams of the example sensor housing 400, with the housing shell 404 removed, in accordance with some aspects of the disclosure. As shown in FIGS. 4B-4D, a desiccant assembly 414 may be disposed with the sensor housing 400. The desiccant assembly 414 may include a desiccant assembly body 420. The desiccant assembly body 420 may include a surface 422 within which is defined with a pocket 424 to form a desiccant chamber 426. The desiccant assembly body 420 may be configured to separate the desiccant chamber 426 from the sensor chamber 402. The pocket 424 may be a recess defined in the surface 422 of the desiccant assembly body 420.

The pocket 424 may be configured to receive at least one desiccant element 428. For example, in the illustrated example, the at least one desiccant element 428 includes two desiccant blocks 428. In some aspects, the at least one desiccant element 428 may be removable. In some other aspects, the at least one desiccant element 428 may be fixed. In some aspects, the at least one desiccant element 428 may include an adhesive material adhered to at least one side of a transfer wall 430. The at least one desiccant element 428 may be either configured to be replaceable at a predetermined service interval, or configured to be permanently integrated and operable for the duration of the expected life of the sensor. In one example, a replaceable desiccant element 428 may be placed in the pocket 424 in a location that is accessible for a maintenance technician to perform a replacement service. In other examples, the at least one desiccant element 428 may be permanently integrated within a sensor (e.g., lidar) assembly and may be placed at any location that advantageously leverages size, weight, space considerations as well as mass balance considerations in cases where the sensor is a mechanical (e.g., spinning or rotating) sensor such as a mechanical lidar. The at least one desiccant element 428 may be shaped in any number of ways to leverage space and performance considerations of the sensor. The at least one desiccant element 428 may be made of a molecular sieve powder mixed with a polymer binder and formed into the desired shape.

FIGS. 4E and 4F are perspective diagrams of the example desiccant assembly body 420, in accordance with some aspects of the disclosure. FIG. 4G is a top plan diagram of the example desiccant assembly body 420, in accordance with some aspects of the disclosure. As shown in FIGS. 4E-4G, for example, the pocket 424 includes a transfer wall 430 having at least one transfer window 432 defined therein. The at least one transfer window 432 may be positioned between the desiccant chamber 426 and the sensor chamber 402. A permeable membrane 434 may be disposed over the at least one transfer window 432 and may be configured to allow water vapor to transfer from the sensor chamber 402 to the desiccant chamber 426. The permeable membrane 434 may be further configured to prevent liquid water and/or particulate matter from transferring from the desiccant chamber 426 to the sensor chamber 402. In some aspects, the permeable membrane 434 and/or a set of dimensions (e.g., area, length, width) of the at least one transfer window 432 may be configured so that a leak rate corresponding to a transfer of water vapor from the sensor chamber 402 to the desiccant chamber 426 causes prevention of condensation of water within the sensor chamber 402.

For example, the permeable membrane 434 may include a material selected so that a leak rate corresponding to a transfer of water vapor from the sensor chamber 402 to the desiccant chamber 426 facilitates maintaining a relative humidity level within the sensor chamber 402 at or below a humidity threshold. In some aspects, the permeable membrane 434 may include a polymer material. For example, the polymer material may include expanded polytetrafluoroethylene (ePTFE). In some aspects, the permeable membrane 434 may be an adhesive material adhered to the transfer wall 430. For example, the permeable membrane 434 may be adhered to an upper surface (e.g., a surface facing the desiccant chamber 426) of the transfer wall 430 and/or to a lower surface (e.g., a surface facing the sensor chamber 402) of the transfer wall 430.

As shown in FIGS. 4B and 4C, the desiccant assembly 414 may include an access component 436 configured to isolate the desiccant chamber 426 from an environment external to the desiccant chamber 426. The access component 436 may include a removable chamber cover 438 configured to be fastened to the surface 422 of the desiccant assembly body 420. The access component 436 may include a seal 440 (e.g., a gasket and/or O-ring) configured to be engaged by the removable chamber cover 438 to seal the desiccant chamber 426 from the outside environment. In some aspects, the top plate 416 may serve as the removable chamber cover 438.

As shown in FIGS. 4B-4D, for example, the desiccant assembly 414 may be disposed within the sensor housing 400. In some aspects, the desiccant assembly 414 may be disposed within the sensor housing 400 at a location that is selected so that a mass balance associated with the sensor housing 400 facilitates a mechanical operation of a sensor within the sensor housing 400 and/or of a mechanical operation of the sensor housing 400 itself. In the illustrated example, the desiccant assembly 414 is located at the top of the sensor housing 400. In some other examples, the desiccant assembly 414 may be located at a bottom of the sensor housing, at a side of the sensor housing 400, and/or at any other location that may be selected to facilitate operation of the sensor. As shown, the desiccant assembly 414 may be coupled to a sensor housing frame 442. In some aspects, the desiccant assembly 414 may be integrated into, or coupled with, the sensor housing shell 404.

In some aspects, the desiccant assembly 414 may include one or more mechanical assemblies configured to open and close, and/or partially open and partially close, the at least one transfer window 432. For example, a mechanical flapper or slider may be configured to cover the at least one transfer window 432 in response to actuation by an actuator. In some aspects, the actuator may be communicatively coupled with the on-board computing device 208 depicted in FIG. 2. In some aspects, the on-board computing device 208 may obtain measurements from one or more environmental sensors (e.g., temperature sensors, humidity sensors, and/or pressure sensors, among other examples), and may cause actuation of the actuator to at least partially open and/or close the at least one transfer window 432 to maintain, based on the measurements, a leak rate corresponding to a transfer of water vapor from the sensor chamber 402 to the desiccant chamber 426 that facilitates maintaining a relative humidity level within the sensor chamber 402 at or below a humidity threshold.

As indicated above, FIGS. 4A-4G are provided as an example. Other examples may differ from what is described with regard to FIGS. 4A-4G. The number and arrangement of components shown in FIGS. 4A-4G are provided as an example. In practice, there may be additional components, fewer components, different components, or differently arranged components than those shown in FIGS. 4A-4G. Furthermore, two or more components shown in FIGS. 4A-4G may be implemented within a single components, or a single components shown in FIGS. 4A-4G may be implemented as multiple, distributed components. Additionally, or alternatively, a set of components (e.g., one or more components) shown in FIGS. 4A-4G may perform one or more functions described as being performed by another set of components shown in FIGS. 4A-4G.

For example, in some aspects, although described herein in the context of sensors, similar desiccant assemblies may be used in conjunction with any type of electronic equipment to prevent condensation within an equipment chamber. For example, an equipment housing may include an equipment chamber configured to hold electronic equipment; and a desiccant assembly. The desiccant assembly may include, as described herein, a desiccant chamber configured to hold a desiccant element; and a transfer assembly positioned between the desiccant chamber and the equipment chamber. The transfer assembly may include at least one transfer window and at least one permeable membrane and may be configured to allow water vapor to transfer from the equipment chamber to the desiccant chamber and to prevent particulate matter from transferring from the desiccant chamber to the equipment chamber.

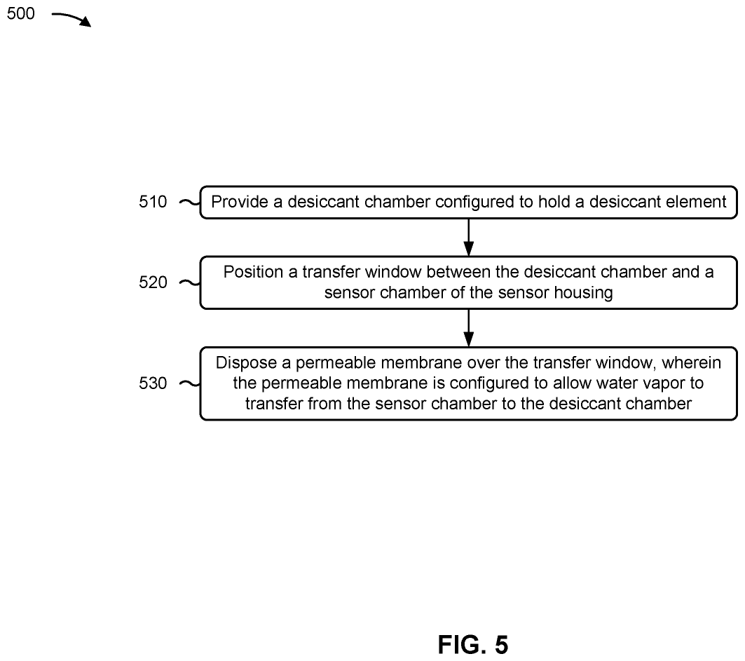

FIG. 5 is a flowchart of an example method 500 associated with manufacturing a sensor housing.

As shown in FIG. 5, the method 500 may include providing a desiccant chamber configured to hold a desiccant element (block 510). As further shown in FIG. 5, the method 500 may include positioning a transfer window between the desiccant chamber and a sensor chamber of the sensor housing (block 520). As further shown in FIG. 5, the method 500 may include disposing a permeable membrane over the transfer window, wherein the permeable membrane is configured to allow water vapor to transfer from the sensor chamber to the desiccant chamber (block 530).

The method 500 may include additional aspects, such as any single aspect or any combination of aspects described below and/or described in connection with one or more other methods or operations described elsewhere herein. In a first aspect, the desiccant chamber comprises a pocket defined in a surface of a desiccant assembly body, the desiccant assembly body configured to separate the desiccant chamber from the sensor chamber. In a second aspect, alone or in combination with the first aspect, the pocket comprises a recess defined in the surface of the desiccant assembly body, the recess comprising a transfer wall within which the transfer window is defined. In a third aspect, alone or in combination with one or more of the first and second aspects, the recess is configured to receive the desiccant element.

In a fourth aspect, alone or in combination with one or more of the first through third aspects, the desiccant element comprises an adhesive material adhered to at least one side of the transfer wall. In a fifth aspect, alone or in combination with one or more of the first through fourth aspects, the desiccant chamber is configured to hold at least one additional desiccant element. In a sixth aspect, alone or in combination with one or more of the first through fifth aspects, the method 500 includes positioning at least one additional transfer window between the desiccant chamber and the sensor chamber. In a seventh aspect, alone or in combination with one or more of the first through sixth aspects, the method 500 includes providing an access component configured to isolate the desiccant chamber from an environment external to the sensor chamber.

In an eighth aspect, alone or in combination with one or more of the first through seventh aspects, providing the access component comprises removably attaching a chamber cover to a surface of desiccant assembly body, the desiccant assembly body configured to separate the desiccant chamber from the sensor chamber. In a ninth aspect, alone or in combination with one or more of the first through eighth aspects, the method 500 includes selecting the permeable membrane so that a leak rate corresponding to a transfer of water vapor from the sensor chamber to the desiccant chamber causes prevention of condensation of water within the sensor chamber. In a tenth aspect, alone or in combination with one or more of the first through ninth aspects, the method 500 includes configuring the permeable membrane to prevent a transfer of liquid water and particulate matter from the desiccant chamber to the sensor chamber. In an eleventh aspect, alone or in combination with one or more of the first through tenth aspects, the permeable membrane comprises a material selected so that a leak rate corresponding to a transfer of water vapor from the sensor chamber to the desiccant chamber facilitates maintaining a relative humidity level within the sensor chamber at or below a humidity threshold. In a twelfth aspect, alone or in combination with one or more of the first through eleventh aspects, the method 500 includes configuring a set of dimensions of the transfer window is so that a leak rate corresponding to a transfer of water vapor from the sensor chamber to the desiccant chamber facilitates maintaining a relative humidity level within the sensor chamber at or below a humidity threshold.

In a thirteenth aspect, alone or in combination with one or more of the first through twelfth aspects, the permeable membrane comprises a polymer material. In a fourteenth aspect, alone or in combination with one or more of the first through thirteenth aspects, the polymer material comprises expanded polytetrafluoroethylene. In a fifteenth aspect, alone or in combination with one or more of the first through fourteenth aspects, the desiccant element is removeable. In a sixteenth aspect, alone or in combination with one or more of the first through fifteenth aspects, the method 500 includes disposing the desiccant assembly within the sensor housing at a location that is selected so that a mass balance associated with the sensor housing facilitates a mechanical operation of a sensor within the sensor housing.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

The foregoing disclosure provides illustration and description, but is not intended to be exhaustive or to limit the implementations to the precise forms disclosed. Modifications may be made in light of the above disclosure or may be acquired from practice of the implementations.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The hardware and/or software code described herein for implementing aspects of the disclosure should not be construed as limiting the scope of the disclosure. Thus, the operation and behavior of the systems and/or methods are described herein without reference to specific software code—it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. Features from different implementations and/or aspects disclosed herein can be combined. For example, one or more features from a method implementations may be combined with one or more features of a device, system, or product implementation. Features described herein may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination and permutation of those items, including single members. As an example, “at least one of: a, b, or c” is intended to cover a, b, c, a-b, a-c, b-c, and a-b-c, as well as any combination with multiple of the same item. As used herein, the term “and/or” used to connect items in a list refers to any combination and any permutation of those items, including single members (e.g., an individual item in the list). As an example, “a, b, and/or c” is intended to cover a, b, c, a-b, a-c, b-c, and a-b-c.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A desiccant assembly within a sensor housing, comprising:
a desiccant chamber configured to hold a desiccant element;
a transfer window positioned between the desiccant chamber and a sensor chamber of the sensor housing; and
a permeable membrane covering the transfer window and configured to allow water vapor to transfer from the sensor chamber to the desiccant chamber.

2. The desiccant assembly of claim 1, wherein the desiccant chamber comprises a pocket defined in a surface of a desiccant assembly body, the desiccant assembly body configured to separate the desiccant chamber from the sensor chamber.

3. The desiccant assembly of claim 2, wherein the pocket comprises a recess defined in the surface of the desiccant assembly body, the recess comprising a transfer wall within which the transfer window is defined.

4. The desiccant assembly of claim 3, wherein the recess is configured to receive the desiccant element.

5. The desiccant assembly of claim 3, wherein the desiccant element comprises an adhesive material adhered to at least one side of the transfer wall.

6. The desiccant assembly of claim 1, wherein the desiccant chamber is configured to hold at least one additional desiccant element.

7. The desiccant assembly of claim 1, further comprising at least one additional transfer window positioned between the desiccant chamber and the sensor chamber.

8. The desiccant assembly of claim 1, further comprising an access component configured to isolate the desiccant chamber from an environment external to the sensor chamber.

9. The desiccant assembly of claim 8, wherein the access component comprises a removable chamber cover.

10. The desiccant assembly of claim 1, wherein the permeable membrane is configured so that a leak rate corresponding to a transfer of water vapor from the sensor chamber to the desiccant chamber causes prevention of condensation of water within the sensor chamber.

11. The desiccant assembly of claim 1, wherein the permeable membrane is configured to prevent a transfer of liquid water and particulate matter from the desiccant chamber to the sensor chamber.

12. The desiccant assembly of claim 11, wherein the permeable membrane comprises a material selected so that a leak rate corresponding to a transfer of water vapor from the sensor chamber to the desiccant chamber facilitates maintaining a relative humidity level within the sensor chamber at or below a humidity threshold.

13. The desiccant assembly of claim 11, wherein a set of dimensions of the transfer window is configured so that a leak rate corresponding to a transfer of water vapor from the sensor chamber to the desiccant chamber facilitates maintaining a relative humidity level within the sensor chamber at or below a humidity threshold.

14. The desiccant assembly of claim 1, wherein the permeable membrane comprises a polymer material.

15. The desiccant assembly of claim 14, wherein the polymer material comprises expanded polytetrafluoroethylene.

16. The desiccant assembly of claim 1, wherein the desiccant element is removeable.

17. The desiccant assembly of claim 1, wherein the desiccant assembly is disposed within the sensor housing at a location that is selected so that a mass balance associated with the sensor housing facilitates a mechanical operation of a sensor within the sensor housing.

18. A lidar system comprising:
a sensor housing including a sensor chamber;
a sensor disposed within the sensor chamber; and
a desiccant assembly disposed within the sensor housing, the desiccant assembly comprising:
a desiccant chamber configured to hold a desiccant element; and
a permeable membrane positioned between the desiccant chamber and the sensor chamber and configured to allow water vapor to transfer from the sensor chamber to the desiccant chamber.

19. The lidar system of claim 18, wherein the permeable membrane is configured so that a leak rate corresponding to a transfer of water vapor from the sensor chamber to the desiccant chamber causes prevention of condensation of water within the sensor chamber.

20. An equipment housing, comprising:
an equipment chamber configured to hold electronic equipment; and
a desiccant assembly, comprising:
a desiccant chamber configured to hold a desiccant element; and
a transfer assembly positioned between the desiccant chamber and the equipment chamber, wherein the transfer assembly is configured to allow water vapor to transfer from the equipment chamber to the desiccant chamber and to prevent particulate matter from transferring from the desiccant chamber to the equipment chamber.
